(19) United States
(12) Patent Application Publication
(10) Pub. No.: US 2024/0178031 A1
(43) Pub. Date: May 30, 2024

(54) SUBSTRATE PROCESSING APPARATUS AND SUBSTRATE PROCESSING METHOD

(71) Applicant: SEMES CO., LTD., Cheonan-si (KR)

(72) Inventors: Sumi Kim, Hwaseong-si (KR); Jaesung Lee, Seoul-si (KR)

(21) Appl. No.: 18/382,239

(22) Filed: Oct. 20, 2023

(30) Foreign Application Priority Data
Nov. 29, 2022 (KR) 10-2022-0163423

(51) Int. Cl. H01L 21/677; H01L 21/67

(52) U.S. Cl. CPC H01L 21/67742; H01L 21/67167; H01L 21/67184; H01L 21/67196; H01L 21/67201; H01L 21/67745

(57) ABSTRACT

A substrate processing apparatus includes a plurality of process chambers for processing a substrate, a first transfer robot configured to transfer the substrate and arranged in a first transfer chamber, a second transfer robot configured to transfer the substrate and arranged in a second transfer chamber, and a share module arranged adjacent to the first transfer chamber and the second transfer chamber and configured to receive the substrate from any one of the first transfer robot and the second transfer robot, wherein an inside of each of the first transfer chamber and the second transfer chamber is in a vacuum state, and the first transfer robot and the second transfer robot transfer the substrate in a vacuum state.

### CROSS-REFERENCE TO RELATED APPLICATION

This application is based on and claims priority under 35 U.S.C. § 119 to Korean Patent Application No. 10-2022-0163423, filed on Nov. 29, 2022, in the Korean Intellectual Property Office, the disclosure of which is incorporated by reference herein in its entirety.

### BACKGROUND

### 1. Field

The disclosure relates to a substrate processing apparatus and a substrate processing method.

### 2. Description of the Related Art

To manufacture semiconductor devices, various semiconductor processes such as photolithography, etching, ashing, ion implantation, thin-film deposition, cleaning, etc. are performed on a substrate to form a desired pattern on the substrate. To perform such various steps of the semiconductor process in a desired order, the substrate needs to be transferred to various positions. The substrate may be transferred by a substrate transfer apparatus among process chambers.

The substrate processing speed may be increased by increasing the number of process chambers in which the semiconductor processes are performed. However, it is difficult to increase the substrate transfer speed of substrate processing apparatuses transferring substrates processed in the process chamber according to the substrate processing speed. This may lead to limitations in increasing the productivity of manufacturing semiconductor devices.

### SUMMARY

Provided are a substrate processing apparatus with improved productivity in substrate processing and a substrate processing method.

The technical task which the technical ideas of the disclosure seek to solve is not limited to the above-mentioned tasks, and other tasks may also be clearly understood by a person skilled in the art from the following descriptions.

Additional aspects will be set forth in part in the description which follows and, in part, will be apparent from the description, or may be learned by practice of the presented embodiments of the disclosure.

According to an aspect of the disclosure, a substrate processing apparatus includes a plurality of process chambers for processing a substrate, a first transfer robot configured to transfer the substrate and arranged in a first transfer chamber, a second transfer robot configured to transfer the substrate and arranged apart from the first transfer robot in a second transfer chamber, and a share module arranged adjacent to the first transfer chamber and the second transfer chamber and configured to receive the substrate from any one of the first transfer robot and the second transfer robot, wherein an inside of each of the first transfer chamber and the second transfer chamber may be in a vacuum state, and the first transfer robot and the second transfer robot may transfer the substrate in a vacuum state.

The first transfer robot may transfer the substrate to a first process chamber in which a first process is performed, among the plurality of process chambers, the second transfer robot may transfer the substrate to a second process chamber in which a second process is performed, among the plurality of process chambers, and the first process may be identical to or different from the second process.

When the second transfer robot is incapable of transferring the substrate, the first transfer robot may transfer the substrate to any one of the first process chamber and the second process chamber.

The first transfer robot and the second transfer robot may be arranged in at least one of a parallel structure in which the first transfer robot and the second transfer robot overlap each other in a vertical direction and a serial structure in which the first transfer robot and the second transfer robot overlap each other in a horizontal direction.

The substrate processing apparatus may further include a plurality of load ports where a container accommodating the substrate is arranged, and the share module may be arranged apart from the plurality of load ports with the first transfer chamber and the second transfer chamber placed therebetween.

The substrate processing apparatus may further include a third transfer robot configured to transfer the substrate and arranged in a third transfer chamber, wherein the first transfer robot and the second transfer robot may be arranged at a same vertical level, and the third transfer robot may be arranged at a level that is lower than the vertical level of the first transfer robot and the second transfer robot.

The third transfer robot may deliver the substrate to any one of the first transfer robot and the second transfer robot.

The share module may include a first connection and a second connection which move the substrate in the share module, and the first connection and the second connection may be ascended or descended by a motor.

An inside of the share module may remain in a vacuum state, and the share module may keep the substrate for a preset time period.

The share module may replace an edge ring arranged on a lateral surface of the substrate.

The first transfer robot and the second transfer robot may be arranged at a same vertical level, and a transfer direction of the first transfer robot may be parallel with a transfer direction of the second transfer robot.

The share module may transfer the substrate in a vertical direction, and the share module may deliver the substrate to any one of the first transfer robot and the second transfer robot.

According to another aspect of the disclosure, a substrate processing apparatus includes a load port for storing a substrate, a load lock module configured to substitute an atmosphere of the substrate, an index robot configured to transfer the substrate between the load port and the load lock module, a plurality of process chambers for processing the substrate, a plurality of transfer robots configured to transfer the substrate to any one of the plurality of process chambers, and a share module configured to replace an edge ring arranged on a lateral surface of the substrate, wherein the load lock module may be arranged between the index robot and the transfer robots and substitute the atmosphere of the substrate with a normal pressure atmosphere or a vacuum atmosphere, the plurality of transfer robots may include an upper transfer robot and a lower transfer robot which is arranged under the upper transfer robot in a vertical direction, and the plurality of transfer robot may transfer the substrate in a vacuum state.

The share module may receive from any one of the plurality of transfer robots a substrate processed in the process chambers and cool the substrate.

The share module may further include a first connection and a second connection which move a substrate in the share module, the first connection may be arranged on the substrate, the second connection may be arranged under the substrate, and the first connection and the second connection may be bellows pipes.

The upper transfer robot and the lower transfer robot may transfer the substrate from the share module to the load lock module.

According to another aspect of the disclosure, a substrate processing method includes providing a substrate to a cassette, transferring the substrate from the cassette to a load lock module and substituting a normal pressure atmosphere of the substrate with a vacuum atmosphere, transferring the substrate to a process chamber and performing a semiconductor process, transferring the substrate to the load lock module after the semiconductor process and substituting the vacuum atmosphere of the substrate with the normal pressure atmosphere, and taking the substrate out to the cassette.

The transferring of the substrate to the process chamber may be performed by a plurality of transfer robots arranged apart from each other.

The plurality of transfer robots may include an upper transfer robot and a lower transfer robot which is arranged under the upper transfer robot in a vertical direction.

The upper transfer robot and the lower transfer robot may transfer different substrates from each other.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a substrate processing apparatus according to an embodiment;

FIG. 2 is a perspective view of a transfer robot according to an embodiment;

FIG. 3 is a schematic cross-sectional view of the substrate processing apparatus of FIG. 1;

FIG. 4 is a plan view of a share module according to an embodiment;

FIGS. 5 and 6 are graphs showing a substrate transfer method used by a substrate processing apparatus according to an embodiment;

FIG. 7 is a schematic cross-sectional view of a substrate processing apparatus according to an embodiment;

FIG. 8 is a schematic plan view of a substrate processing apparatus according to an embodiment;

FIG. 9 is a flowchart illustrating a transfer path of a substrate according to an embodiment;

FIG. 10 is a flowchart illustrating a transfer path of a substrate according to another embodiment;

FIG. 11 is a flowchart illustrating a substrate processing method according to an embodiment; and

FIG. 12 is a graph showing effects of a substrate processing apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments are described in detail referring to the attached drawings. In describing the embodiments in relation to the accompanying drawings, like reference numerals denote like or corresponding elements, and any redundant description will be omitted.

When a portion “includes” an element, another element may be further included, rather than excluding the existence of the other element, unless otherwise described. Further, the terms such as “include” or “have” in various embodiments of the disclosure are used to specify the existence of features, numbers, processes, operations, components, parts recited in the detailed description, or combinations thereof, and thus should not be understood as pre-excluding the existence or possibility for addition of one or more other features, numbers, processes, operations, components, parts, or combinations thereof.

While such terms as “first,” “second,” etc., may be used to describe various components, such components must not be limited to the above terms. The above terms are used only to distinguish one component from another. For examples, a first component may be named as a second components, and similarly, a second components may be named as a first component without departing from the scope of rights of the disclosure.

An expression used in the singular encompasses the expression of the plural, unless it has a clearly different meaning in the context. The shapes and sizes of components in the drawings may be exaggerated for clear exposition.

Hereinafter, embodiments of the disclosure will be described in detail with reference to the drawings.

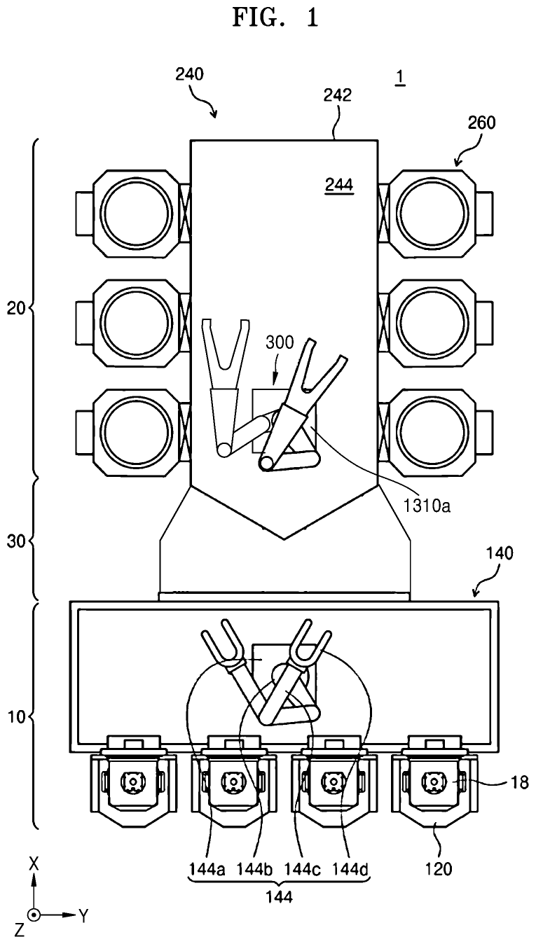

FIG. 1 is a schematic plan view of a substrate processing apparatus according to an embodiment.

Referring to FIG. 1, a substrate processing apparatus 1 may include an equipment front end module (EFEM) 10, a load lock module 30, and a process module 20. The substrate processing apparatus 1 may also include semiconductor vacuum equipment.

The EFEM 10 may include a load port 120 and an atmosphere transfer robot (ATR) unit 140. The load port 120, the ATR unit 140, and the process module 20 may be arranged sequentially along a line.

Hereinafter, a direction in which the load port 120, the ATR unit 140, the load lock module 30, and the process module 20 are arranged may be referred to as a first direction (for example, an X-axis direction), a direction perpendicular to the first direction may be referred to as a second direction (for example, Y-axis direction), and a direction perpendicular to a plane including the first direction and the second direction may be referred to as a third direction (for example, a Z-axis direction).

In the disclosure, the load lock module 30 and the process module 20 may be collectively referred to as a process module.

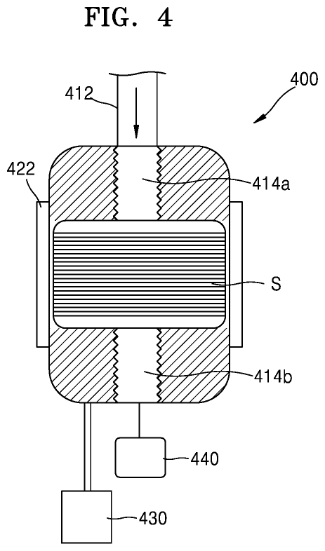

The load port 120 may include a cassette 18. The cassette 18 may store a plurality of substrates S (refer to FIG. 4). A plurality of load ports 120 may be arranged along a line in the second direction. Although only four load ports 120 are illustrated in FIG. 1, the disclosure is not limited thereto. The number of load ports 120 may be increased or reduced according to a process efficiency, conditions of footprint, etc. of the process module 20.

The cassette 18 may include a slot (not shown) provided to support an edge of the substrate. A plurality of slots may be arranged in the third direction. The substrates S may be stacked in the cassette 18 to be apart from each other in the third direction. A front opening unified pod (FOUP) may be used as the cassette 18.

The ATR unit 140 may include an ATR 144. The ATR unit 140 may transfer the substrate between the cassette 18 settled on the load port 120 and the load lock module 30. The EFEM 10 may have a plurality of ATRs. The ATR 144 may be fixed in the ATR unit 140.

The ATR 144 may include a base 144a, a body 144b, an arm 144c, and a hand 144d. The body 144b may be coupled to the base 144a. The body 144b may be movable in the third direction on the base 144a. In addition, the body 144b may be rotatable on the base 144a. The arm 144c may be coupled to the body 144b and may move forward and backward with respect to the body 144b. There may be a plurality of arms 144c which may be operated individually. The arms 144c may be stacked while being apart from each other in the third direction. Any one of the plurality of arms 144c may be used when transferring the substrate S from the process module 20 to the cassette 18. In addition, another arm of the plurality of arms 144c may be used when transferring the substrate S from the cassette 18 to the process module 20. This may prevent particles generated from an unprocessed substrate S while the ATR 144 carries in and takes out substrates S from adhering to a processed substrate S.

The load lock module 30 may be arranged between the ATR unit 140 and a transfer unit 240. With respect to the substrate S brought into the process module 20, the load lock module 30 may substitute a normal pressure atmosphere of the EFEM 10 with a vacuum atmosphere of the process module 20. In addition, as for the substrate S taken out to the EFEM 10, the load lock module 30 may substitute the vacuum atmosphere of the process module 20 with the normal pressure atmosphere of the EFEM 10. The load lock module 30 may provide a space in which the substrate S stays (for example, a storage space) before the substrate S is transferred between the transfer unit 240 and the ATR unit 140.

The load lock module 30 may temporarily keep the substrate S to be transferred from the EFEM 10 to the process module 20. The load lock module 30 may remain in a normal pressure atmosphere in the standby status and may be blocked to the process module 20 while being opened to the EFEM 10. When the substrate S is brought into the load lock module 30, an interior space of the load lock module 30 may be sealed against each of the EFEM 10 and the process module 20. Then, the interior space of the load lock module 30 may be switched from the normal pressure atmosphere to the vacuum atmosphere and may be opened to the process module 20 while being blocked to the EFEM 10.

The load lock module 30 may temporarily keep the substrate S to be transferred from the process module 20 to the EFEM 10. The load lock module 30 may remain in a vacuum atmosphere in the standby status and may be blocked to the EFEM 10 while being opened to the process module 20. When the substrate S is brought into the load lock module 30, the interior space of the load lock module 30 may be sealed against each of the EFEM 10 and the process module 20. Then, the interior space of the load lock module 30 may be switched from the vacuum atmosphere to the normal pressure atmosphere and may be opened to the EFEM 10 while being blocked to the process module 20.

The process module 20 may include the transfer unit 240 and a plurality of process chambers 260. The process chambers 260 may perform a semiconductor process by which substrates are processed by using plasma. However, the disclosure is not limited thereto, and the process chambers 260 may perform a semiconductor process without using plasma. According to embodiments, the semiconductor process may be a cleaning process, an etching process, or a thin-film deposition process.

The transfer unit 240 may transfer the substrate between the load lock module 30 and the plurality of process chambers 260. The transfer unit 240 may include a transfer chamber 242 and a transfer robot 310.

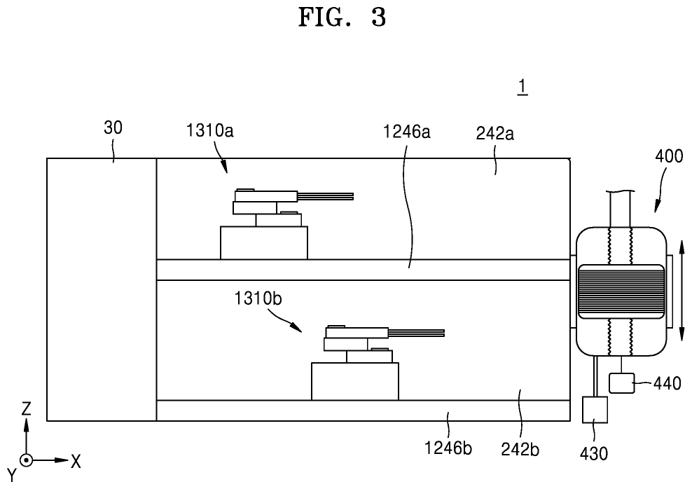

The transfer robot 310 may include an upper transfer robot 1310a and a lower transfer robot 1310b which are stacked vertically in the third direction. The transfer robot 310 may include a plurality of arms. In embodiments, one transfer robot 310 may include at least two arms. Although FIG. 1 illustrates only the upper transfer robot 1310a of the transfer robot 310, a lower transfer robot 1310b may be arranged under the upper transfer robot 1310a (see FIG. 3). The upper and lower transfer robots will be further described in detail later in relation to FIG. 3.

The transfer chamber 242 may be provided in a rectangular shape. The transfer chamber 242 may be provided in various shapes. The plurality of process chambers 260 may be arranged on both surfaces of the transfer chamber 242. The transfer chamber 242 may include a transfer space 244 for transferring the substrate S. The transfer space 244 may be provided in a vacuum environment.

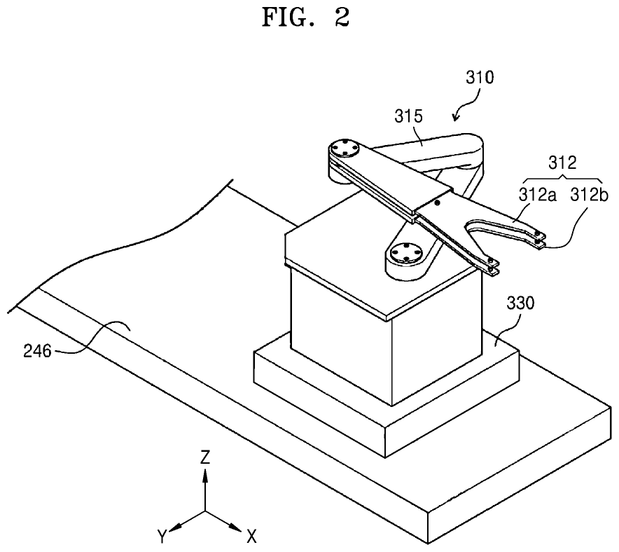

FIG. 2 is a perspective view of the transfer robot 310 according to an embodiment.

Now, embodiments are described referring to FIG. 1, and any redundant description related to FIG. 1 will be omitted.

Referring to FIG. 2, the substrate processing apparatus 1 may include the transfer robot 310. The transfer robot 310 may transfer the substrate S in the transfer space 244. The transfer robot 310 may move in the X-axis direction (for example, the first direction).

The transfer robot 310 may move in the horizontal direction and the vertical direction, and may include a plurality of hands 312a and 312b which are capable of moving forward and backward or rotating on a horizontal plane. The plurality of hands 312a and 312b may be a robot arm 312. Each of the plurality of hands 312a and 312b may be operated independently. The substrate S may be settled on the hands 312a and 312b horizontally. In addition, the transfer robot 310 may include an arm driving module 315 configured to drive the robot arm 312.

The hands 312a and 312b may be provided in various shapes. In some embodiments, the hands 312a and 312b may be provided in a Y shape to facilitate reception and transfer of the substrate and other members from and to other components. The embodiments illustrates and describes the shape of the hands 312a and 312b as a “Y” shape; however, the shape of the hands 312a and 312b may be changed to various shapes including an “I” shape, etc.

FIG. 3 is a schematic cross-sectional view of the substrate processing apparatus of FIG. 1.

Referring to FIGS. 1 and 3, the transfer robot 310 may include the upper transfer robot 1310a and the lower transfer robot 1310b. The upper transfer robot 1310a and the lower transfer robot 1310b may move in the first direction (for example, X-axis direction). The transfer direction of the upper transfer robot 1310a may be parallel with the transfer direction of the lower transfer robot 1310b. The transfer direction may refer to a direction in which the upper transfer robot 1310a or the lower transfer robot 1310b moves to transfer the substrate.

Each of the upper transfer robot 1310a and the lower transfer robot 1310b may transfer the substrate S from the load lock module 30 to the process chambers 260. The upper transfer robot 1310a and the lower transfer robot 1310b may be stacked in the third direction (for example, Z-axis direction). In some embodiments, the lower transfer robot 1310b may be arranged under the upper transfer robot 1310a.

The upper transfer robot 1310a may be arranged in a first transfer chamber 242a. In addition, the lower transfer robot 1310b may be arranged in a second transfer chamber 242b. The first transfer chamber 242a and the second transfer chamber 242b may be stacked vertically in the third direction. The upper transfer robot 1310a may move in the first transfer chamber 242a in the first direction (for example, X-axis direction), and the lower transfer robot 1310b may move in the second transfer chamber 242b in the first direction.

The upper transfer robot 1310a and the lower transfer robot 1310b may transfer different substrates from each other and transfer the substrate to different process chambers 260 from each other. In some embodiments, the upper transfer robot 1310a may transfer the substrate to the first process chamber in which a first process is performed. In some embodiments, the lower transfer robot 1310b may transfer the substrate to the second process chamber in which a second process is performed. The first process performed in the first process chamber may be different from the second process performed in the second process chamber. In some embodiments, the upper transfer robot 1310a may transfer the substrate to a plurality of first process chambers performing the same process, and the lower transfer robot 1310b may transfer the substrate to a plurality of second process chambers performing a process different from the process performed in the plurality of first process chambers.

In some embodiments, the upper transfer robot 1310a may transfer the substrate S from the load lock module 30 to any one of the plurality of process chambers 260. In some embodiments, the lower transfer robot 1310b may transfer the substrate S from the load lock module 30 to any one of the plurality of process chambers 260.

In some embodiments, the upper transfer robot 1310a may transfer the substrate S from any one of the plurality of process chambers 260 finished with the process to a share module 400. The lower transfer robot 1310b may transfer the substrate S from the share module 400 to the load lock module 30. Alternatively, the upper transfer robot 1310a and the lower transfer robot 1310b may transfer the substrate in the opposite way from the above.

In some embodiments, among the plurality of process chambers 260, process chambers facing each other with the transfer chamber 242 therebetween may be arranged apart from each other in the third direction. For example, among the plurality of process chambers 260, the first process chamber and the second process chamber which face each other may be arranged at different vertical levels from each other. More specifically, the vertical height of the first process chamber in the third direction may be greater than the vertical height of the second process chamber in the third direction. In this case, the upper transfer robot 1310a may transfer the substrate S to the first process chamber, and the lower transfer robot 1310b may transfer the substrate S to the second process chamber.

In some embodiments, the plurality of process chambers 260 may have the same height in the third direction. In this case, the upper transfer robot 1310a and the lower transfer robot 1310b may move in the vertical direction to store the substrates S in the plurality of process chambers 260.

In some embodiments, while the upper transfer robot 1310a transfers the substrate S from the load lock module 30 to any one of the plurality of process chambers 260, the lower transfer robot 1310b may transfer the substrate S from a process chamber finished with the process among the plurality of process chambers 260 to the load lock module 30. In some embodiments, while the upper transfer robot 1310a transfers the substrate S from a process chamber finished with the process among the plurality of process chambers 260 to the load lock module 30, the lower transfer robot 1310b may transfer the substrate S from the load lock module 30 to any one of the plurality of process chambers 260.

In some embodiments, the upper transfer robot 1310a may transfer the substrate S from the load lock module 30 to the process chambers 260, and the lower transfer robot 1310b may transfer the substrate S from the process chambers 260 to the load lock module 30. That is, the upper transfer robot 1310a may be in charge of transfer of the substrate S from the load lock module 30 to the process chambers 260 and the lower transfer robot 1310b may be in charge of transfer of the substrate S from the process chambers 260 to the load lock module 30.

Referring to FIGS. 1 and 3, by vertically stacking the upper transfer robot 1310a and the lower transfer robot 1310b in the third direction, the substrate S may be transferred efficiently from the load lock module 30 to the process chambers 260. Moreover, by vertically stacking the upper transfer robot 1310a and the lower transfer robot 1310b in the third direction, the substrate S may be transferred efficiently from the process chambers 260 to the load lock module 30. As the upper transfer robot 1310a and the lower transfer robot 1310b respectively transfer different substrates S from each other to the process chambers 260, the transfer speed of substrate may be improved. In addition, even when the number of process chambers 260 increases, the substrate may be transferred quickly according to the processing speed. Thus, the substrate productivity may be improved.

The share module 400 is described in detail in relation to FIG. 4.

FIG. 4 is a cross-sectional view of a share module according to an embodiment. Now, embodiments are described referring to FIG. 3, and any redundant description related to FIG. 3 will be omitted.

Referring to FIG. 4, the share module 400 may include an inflow tube 412, a slit portion 422, a door portion 424, a first connection 414a, a second connection 414b, a pump 430, and a motor 440.

The share module 400 may be arranged adjacent to the first transfer chamber 242a in which the upper transfer robot 1310a is arranged and the second transfer chamber 242b in which the lower transfer robot 1310b is arranged. In some embodiments, the share module 400 may be in contact with the first transfer chamber 242a and the second transfer chamber 242b. The inside of the share module 400 may be maintained in a vacuum state. The share module 400 may keep the substrate for a preset time period. The share module 400 may keep an edge ring which needs to be replaced in the process chambers in a vacuum state. The share module 400 may change the inside of the share module 400 into the normal pressure state. The share module 400 may provide the edge ring to an external device.

The share module 400 may move in the third direction (for example, Z direction) through the first connection 414a and the second connection 414b. The share module 400 may rise and fall through the first connection 414a and the second connection 414b and move in the third direction.

Through this, the share module 400 may deliver the substrate placed in the share module 400 to the upper transfer robot 1310a of the first transfer chamber 242a or to the lower transfer robot 1310b of the second transfer chamber 242b. The slit portion of the share module 400 may be opened or closed to deliver or receive the substrate to or from the upper transfer robot 1310a or the lower transfer robot 1310b. The first connection 414a and the second connection 414b may receive energy through the motor 440 connected to the bottom of the share module 400 and may rise or fall. The first connection 414a and the second connection 414b may include a bellows pipe.

The share module 400 may receive the substrate from any one of the upper transfer robot 1310a and the lower transfer robot 1310b. In some embodiments, the share module 400 may keep the received substrate. In addition, the share module 400 may keep the edge ring of the substrate. The door portion 424 may be opened or closed to replace the edge ring. The replacement of the edge ring may be performed in a vacuum state. The edge ring may be arranged on a lateral surface of the substrate. The edge ring may be prevent damage due to plasma. Moreover, the edge ring may increase the time of a liquid chemical, etc. staying on the substrate. However, the disclosure is not limited thereto.

In some embodiments, the share module 400 may cool a heated substrate. In this regard, nitrogen (N2) may be flow in through the inflow tube 412, and the share module 400 may cool the substrate by using the nitrogen.

In some embodiments, the share module 400 may cool a heated substrate S. A flow path of cooling water may be disposed in the share module 400, and the share module 400 may cool the substrate S by using the cooling water.

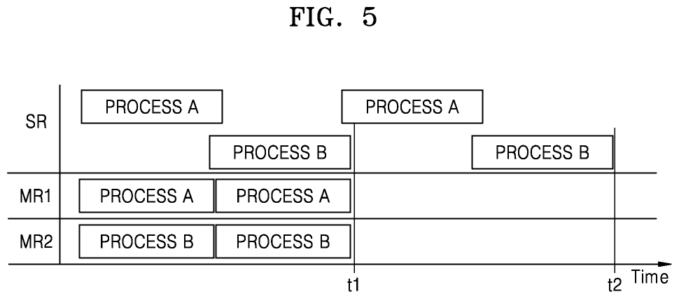

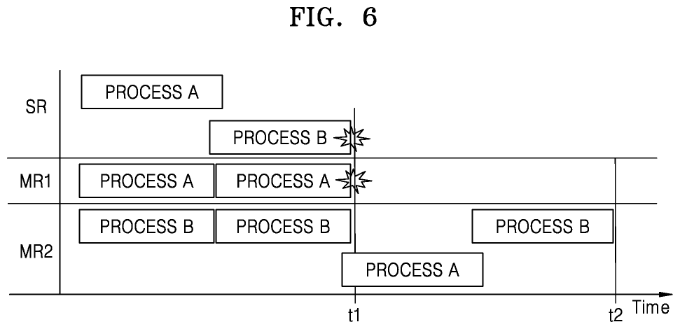

FIGS. 5 and 6 are graphs showing a substrate transfer method of a substrate processing apparatus according to an embodiment. Now, embodiments are described referring to FIGS. 3 and 4, and any redundant description related to FIGS. 3 and 4 will be omitted. Here, SR represents a single transfer robot in a comparative example. MR1 represents the upper transfer robot 1310a, and MR2 represents the lower transfer robot 1310b. PROCESS A represents the first process chamber in which the first process is performed, and the PROCESS B represents the second process chamber in which the second process is performed. PROCESS A and PROCESS B listed in the horizontal direction represent different chambers from each other.

Referring to FIG. 5, in a comparative example, the single transfer robot SR may transfer a substrate alternately to the first process chamber PROCESS A in which the first process is performed and the second process chamber PROCESS B in which the second process is performed. When the single transfer robot SR transfers a plurality of substrates, time t2 is required.

As for the transfer robots MR1 and MR2, the transfer robot MR1 may transfer the substrate to the first process chamber in which the first process is performed, and the transfer robot MR2 may transfer the substrate to the second process chamber in which the second process is performed. That is, the transfer robot MR1 may transfer the substrate to the plurality of chambers in which the first process is performed, and the transfer robot MR2 may transfer the substrate to the plurality of cambers in which the second process is performed. When the plurality of transfer robots (for example, MR1 and MR2) transfer the substrate, time t1 is required.

As such, the plurality of transfer robots (for example, MR1 and MR2) of the disclosure may reduce the substrate transfer time and improve the transfer efficiency. In addition, as the transfer robot MR1 transfers the substrate only to the plurality of first process chambers in which the first process is performed, and the transfer robot MR2 transfers the substrate only to the plurality of second process chambers in which the second process is performed, contamination of substrate due to different processes may be prevented. Accordingly, defects in the substrates may be prevented, and the productivity may be improved.

FIG. 6 illustrates a case where a problem arises with respect to the transfer robot (for example, SR or MR1). According to the comparative example, when a problem arises from the single transfer robot SR, the substrate may no longer be transferred to the process chamber (for example, the first process chamber or the second process chamber). In comparison, when a problem is caused to the transfer robot MR1 of the disclosure, the transfer robot MR2 may still be able to transfer the substrate. In addition, like the single transfer robot SR, the transfer robot MR2 may transfer the substrate alternately to the first process chamber and the second process chamber. That is, according the disclosure, as a plurality of transfer robots are used to transfer the substrate, even when a problem is caused to any one of the plurality of transfer robots, the substrate may still be transferred. Moreover, even when a problem occurs, another transfer robot may continue to transfer the substrate, which minimizes effects on the productivity.

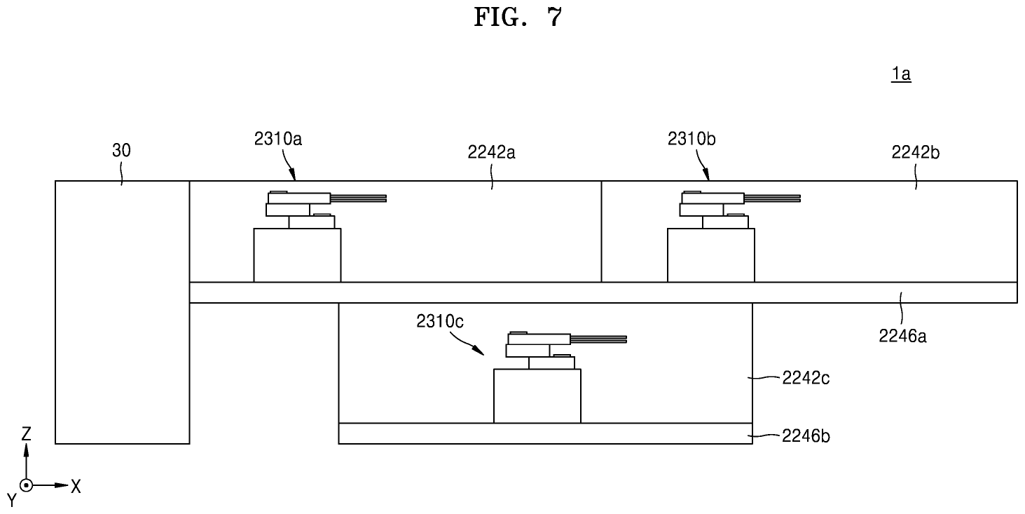

FIG. 7 is a schematic cross-sectional view of a substrate processing apparatus according to an embodiment. Now, embodiments are described referring to FIGS. 1 to 4, and any redundant description will be omitted.

Referring to FIG. 7, a substrate processing apparatus 1a may include a first transfer robot 2310a, a second transfer robot 2310b, and a third transfer robot 2310c. The first transfer robot 2310a may be arranged in a first transfer chamber 2342a, the second transfer robot 2310b may be arranged in a second transfer chamber 2342b, and the third transfer robot 2310c may be arranged in a third transfer chamber 2342c.

The first transfer robot 2310a and the second transfer robot 2310b may be arranged in a serial structure in which the first transfer robot 2310a and the second transfer robot 2310b are connected to each other in series. The first transfer robot 2310a and the third transfer robot 2310c may be arranged in a parallel structure in which the first transfer robot 2310a and the third transfer robot 2310c are apart from each other in the third direction (for example, the vertical direction). The first to third transfer robots 2310a, 2310b, and 2310c may be arranged in at least one of the parallel structure and the serial structure. The first and second transfer robots 2310a and 2310b and the third transfer robot 2310c may have a multi-layer structure in which the first and second transfer robots 2310a and 2310b partially overlap the third transfer robot 2310c in the third direction.

The transfer direction of the first transfer robot 2310a may be parallel with the transfer direction of the third transfer robot 2310c. The second transfer robot 2310b and the third transfer robot 2310c may be arranged in a parallel structure in which the second transfer robot 2310b and the third transfer robot 2310c are apart from each other in the third direction. The transfer direction of the second transfer robot 2310b may be parallel with the transfer direction of the third transfer robot 2310c. The third transfer robot 2310c may be arranged under the first transfer robot 2310a and the second transfer robot 2310b.

The first transfer robot 2310a may be parallel with the third transfer robot 2310c in the vertical direction (for example, the third direction). The second transfer robot 2310b may be parallel with the third transfer robot 2310c in the vertical direction. The first transfer robot 2310a may transfer the substrate S to the third transfer robot 2310c. The second transfer robot 2310b may transfer the substrate S to the third transfer robot 2310c.

The third transfer robot 2310c may transfer the substrate S between the transfer robots. More specifically, the third transfer robot 2310c may transfer the substrate S from the first transfer robot 2310a to the second transfer robot 2310b. In addition, the third transfer robot 2310c may deliver the substrate S from the second transfer robot 2310b to the first transfer robot 2310a.

In some embodiments, the first transfer robot 2310a may transfer the substrate S from the load lock module 30 to any one of the process chambers 260, the second transfer robot 2310b, and the third transfer robot 2310c. The second transfer robot 2310b may receive the substrate S from the first transfer robot 2310a or the third transfer robot 2310c and transfer the substrate S to any one of the plurality of process chambers 260.

In some embodiments, the second transfer robot 2310b may transfer the substrate S from a process chamber finished with the process among the plurality of process chambers 260 to the first transfer robot 2310a or the third transfer robot 2310c. In addition, the third transfer robot 2310c may transfer the substrate S from the second transfer robot 2310b to the first transfer robot 2310a. The first transfer robot 2310a may transfer the substrate S from the second transfer robot 2310b to the load lock module 30.

As each of the first transfer robot 2310a and the second transfer robot 2310b transfers the substrate S to the process chambers 260 or transfers the substrate S from the process chambers 260, and the third transfer robot 2310c transfers the substrate S to the first transfer robot 2310a or the second transfer robot 2310b, the transfer of the substrate S may be performed separately among the transfer robots. Through this, the substrate S may be transferred systematically, and the substrate transfer time may be reduced. The productivity of the substrate S may increase proportionally to an increase in the number of the process chambers 260. Accordingly, the transfer delay of the substrate S caused by the transfer robots in related arts may be prevented, which leads to maximized productivity of substrate.

Although it is not shown in the drawings, the share module 400 of FIGS. 2 and 3 may be arranged adjacent to the second transfer chamber 2342b. In some embodiments, the share module 400 may receive the substrate from the second transfer robot 2310b. In addition, the share module 400 may cool the received substrate and keep the edge ring arranged on the lateral surface of the substrate.

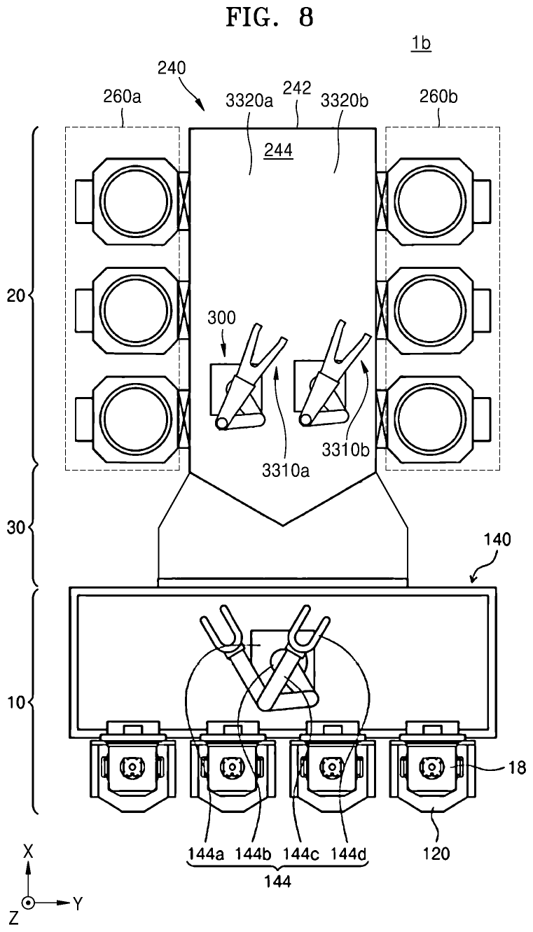

FIG. 8 is a schematic plan view of a substrate processing apparatus according to an embodiment.

Referring to FIG. 8, a substrate processing apparatus 1b may have a similar structure to the structure illustrated in FIG. 1, except that the substrate processing apparatus 1b includes a first transfer robot 3310a and a second transfer robot 3310b. The components of the embodiment may be understood by referring to the descriptions of the same or similar components of the substrate processing apparatus 1 illustrated in FIG. 1, unless otherwise described.

The first transfer robot 3310a may move in the first direction (for example, X-axis direction). The second transfer robot 3310b may move in the first direction. The transfer direction of the first transfer robot 3310a may be parallel with the transfer direction of the second transfer robot 3310b. The second transfer robot 3310b may be arranged on a side of the first transfer robot 3310a in the second direction. That is, the first transfer robot 3310a and the second transfer robot 3310b may be arranged in a parallel structure in which the first transfer robot 3310a and the second transfer robot 3310b are parallel with each other in the horizontal direction.

Each of the first transfer robot 3310a and the second transfer robot 3310b may be arranged on a bottom surface of the transfer chamber 242. That is, each of the first transfer robot 3310a and the second transfer robot 3310b may be arranged at the same vertical level in the third direction (for example, Z-axis direction).

The plurality of process chambers 260 may include first process chambers 260a arranged adjacent to the first transfer robot 3310a and second process chambers 260b arranged adjacent to the second transfer robot 3310b.

In some embodiments, the first transfer robot 3310a may transfer the substrate S from the load lock module 30 to the first process chambers 260a. In addition, after the process is completed, the first transfer robot 3310a may transfer the substrate S from the first process chambers 260a to the load lock module 30. In some embodiments, the second transfer robot 3310b may transfer the substrate S from the load lock module 30 to the second process chambers 260b. In addition, after the process is completed, the second transfer robot 3310b may transfer the substrate S from the second process chambers 260b to the load lock module 30. Through this, each of the first transfer robot 3310a and the second transfer robot 3310b may transfer the substrate S to adjacent process chambers 260. The substrate processing apparatus 1b may assign the process chambers to the transfer robots to transfer the substrates. This may reduce the transfer time of the substrate S and maximize the productivity of the substrate S. In some embodiments, the transfer chamber 242 may be divided into a first transfer chamber 3320a and a second transfer chamber 3320b. The first transfer robot 3310a may move in the first transfer chamber 3320a, and the second transfer robot 3310b may move in the second transfer chamber 3320b.

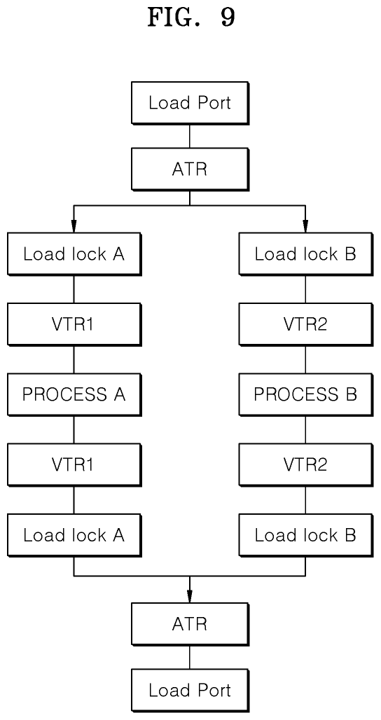

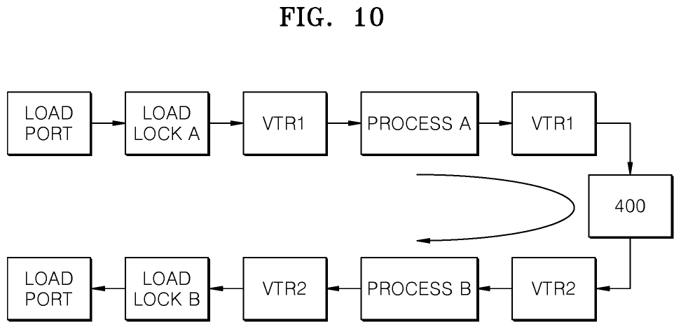

FIG. 9 is a flowchart illustrating a transfer path of a substrate according to an embodiment. FIG. 10 is a flowchart illustrating a transfer path of a substrate according to another embodiment.

Referring to FIG. 9, the plurality of substrates may be stored in the load port and via the ATR, may be transferred to a load lock A and a load lock B. A first vacuum transfer robot VTR1 may transfer a substrate stored in the load lock A to the first process chamber PROCESS A in which the first process is performed. In addition, a second vacuum transfer robot VTR2 may transfer a substrate stored in the load lock B to the second process chamber PROCESS B in which the second process is performed. The first vacuum transfer robot VTR1 may be any one of the upper transfer robot 1310a and the first transfer robot 2310a illustrated in FIGS. 3 and 7. The second vacuum transfer robot VTR2 may be any one of the lower transfer robot 1310b and the second transfer robot 2310b.

After the first process is completed, the first vacuum transfer robot VTR1 may transfer the substrate back to the load lock A. Similarly, after the second process is completed, the second vacuum transfer robot VTR2 may transfer the substrate to the load lock B. Thereafter, the substrate may be stored in the load port via the ATR.

As such, the plurality of substrates may be transferred in parallel through the first vacuum transfer robot VTR1 and the second vacuum transfer robot VTR2. Accordingly, the substrate transfer time may be reduced, and the productivity may be improved.

Referring to FIG. 10, the substrate may be stored in the load lock A (or load lock chamber A) LOAD LOCK A of the load lock module 30 via the load port. The first vacuum transfer robot VTR1 may transfer the substrate to the first process chamber PROCESS A, and after the first process is completed, the first vacuum transfer robot VTR1 may transfer the substrate to the share module 400. In the share module 400, the substrate may be cooled. Then, the second vacuum transfer robot VTR2 may transfer the substrate from the share module 400 to the second process chamber PROCESS B. After the second process is completed, the second vacuum transfer robot VTR2 may transfer the substrate to the load lock B and then store in the load port via the load lock B (or load lock chamber B) LOAD LOCK B of the load lock module 30. By doing so, a circulation structure in which the substrates are transferred via the share module may be formed. As for the substrate, the semiconductor process, replacement of the edge ring, the cooling process, etc. are performed in a vacuum state, the substrate processing apparatus of the disclosure may improve the reliability of the substrate.

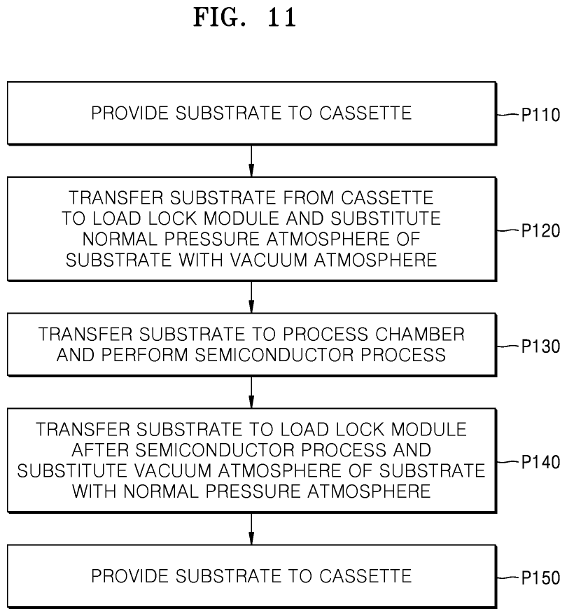

FIG. 11 is a flowchart illustrating a substrate processing method according to an embodiment.

Referring to FIGS. 1 and 11, the substrate processing method of the embodiment may first include providing the substrate S to the cassette 18 (P110). The cassette 18 may be settled on the load port 120. The substrate S may be stored in the cassette 18, and the plurality of substrates S may be stacked and stored in the cassette 18.

After the substrate S is stored in the cassette 18, the substrate S may be transferred from the cassette 18 to the load lock module 30, and the normal pressure atmosphere of the substrate S may be substituted with the vacuum atmosphere (P120). The ATR 144 may transfer the substrate S from the cassette 18 to the load lock module 30. The normal pressure atmosphere may refer to a state in which no separate decompressor such as a vacuum pump, etc. is applied. In addition, the vacuum atmosphere may refer to a pressure of 1 atm or less.

After the normal pressure atmosphere is substituted with the vacuum atmosphere, the substrate S may be transferred to the process chamber, and then the semiconductor process may be performed (P130). The semiconductor process may refer to any one of the etching process and the thin-film deposition process using plasma. The etching process may be a dry etching process. The thin-film deposition process may be a process forming a thin-film required for etching. The process chamber may be any one of the plurality of process chambers 260. The transfer robot 310 may transfer the substrate S from a load lock module 30 to the process chamber.

After the semiconductor process, the substrate S may be transferred to the load lock module 30, and the vacuum atmosphere of the substrate S may be substituted with the normal pressure atmosphere (P140). The transfer robot 310 may transfer the substrate S from the process chamber to the load lock module 30.

In operations P130 and P140, the transfer robot 310 may be the plurality of transfer robots described above in relation to FIGS. 1 and 3 to 5. That is, the substrate S may be transferred by a plurality of transfer robots. The plurality of transfer robots may be arranged apart from each other in a serial structure or in a parallel structure. For example, the plurality of transfer robots may include an upper transfer robot and a lower transfer robot which is arranged under the upper transfer robot in a vertical direction. In addition, the upper transfer robot and the lower transfer robot may transfer different substrates S from each other.

The substrate S of which atmosphere is substituted with the normal pressure atmosphere may be provided to the cassette (P150). The ATR 144 may transfer the substrate S from the load lock module 30 to the cassette 18.

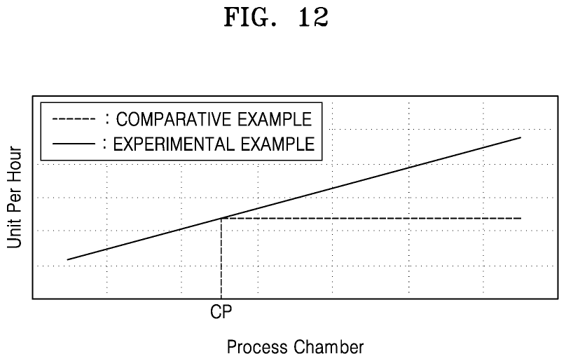

FIG. 12 is a graph showing effects of the substrate processing apparatus 1 according to an embodiment.

Referring to FIG. 12, the horizontal axis represents the number of process chambers (PC), and the vertical axis represents units per hour (UPH) of the substrate. The unit of the vertical axis is a production number per hour. The dotted line shows a substrate production amount of a conventional substrate processing apparatus in a comparative example, and the solid line shows a substrate production amount of the substrate processing apparatus according to an embodiment of the disclosure in an experimental example.

In related arts, substrate processing apparatuses related to semiconductor vacuum equipment do not include a plurality of transfer robots. Due to this, the production of the substrate face a certain limit from a point where the number of process chambers exceeds a certain value. On the contrary, according to the experimental example of the disclosure, as a plurality of transfer robots capable of transferring the substrate in a vacuum state are arranged in a parallel structure or in a serial structure, when the number of process chambers increases, the production of the substrate may increase accordingly. As such, by arranging a plurality of transfer robots capable of transferring the substrates in a vacuum state, the productivity of the substrate may be improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
a plurality of process chambers for processing a substrate;
a first transfer robot configured to transfer the substrate and arranged in a first transfer chamber;
a second transfer robot configured to transfer the substrate and arranged apart from the first transfer robot in a second transfer chamber; and
a share module arranged adjacent to the first transfer chamber and the second transfer chamber and configured to receive the substrate from any one of the first transfer robot and the second transfer robot,
wherein an inside of each of the first transfer chamber and the second transfer chamber is in a vacuum state, and
the first transfer robot and the second transfer robot each transfer the substrate in a vacuum state.

2. The substrate processing apparatus of claim 1, wherein the first transfer robot transfers the substrate to a first process chamber in which a first process is performed, among the plurality of process chambers,
the second transfer robot transfers the substrate to a second process chamber in which a second process is performed, among the plurality of process chambers, and
the first process is different from the second process.

3. The substrate processing apparatus of claim 2, wherein, when the second transfer robot is incapable of transferring the substrate, the first transfer robot transfers the substrate to any one of the first process chamber and the second process chamber.

4. The substrate processing apparatus of claim 1, wherein the first transfer robot and the second transfer robot are arranged in at least one of a parallel structure in which the first transfer robot and the second transfer robot overlap each other in a vertical direction and a serial structure in which the first transfer robot and the second transfer robot overlap each other in a horizontal direction.

5. The substrate processing apparatus of claim 4, wherein the share module is placed between the first transfer chamber and the second transfer chamber, and
the share module is arranged to ascend or descend to allow any one of the first transfer robot and the second transfer robot to deliver the substrate to the other one of the first transfer robot and the second transfer robot.

6. The substrate processing apparatus of claim 1, further comprising a third transfer robot configured to transfer the substrate and arranged in a third transfer chamber,
wherein the first transfer robot and the second transfer robot are arranged at the same vertical level, and
the third transfer robot is arranged at a level that is lower than the vertical level of the first transfer robot and the second transfer robot.

7. The substrate processing apparatus of claim 6, wherein the third transfer robot delivers the substrate to any one of the first transfer robot and the second transfer robot.

8. The substrate processing apparatus of claim 6, wherein the share module includes a first connection and a second connection which move a substrate in the share module, and
the first connection and the second connection are ascended or descended by a motor.

9. The substrate processing apparatus of claim 1, wherein an inside of the share module remains in a vacuum state, and
the share module keeps the substrate for a preset time period.

10. The substrate processing apparatus of claim 1, wherein the share module keeps an edge ring which needs to be replaced in the process chambers in a vacuum state.

11. The substrate processing apparatus of claim 1, wherein the first transfer robot and the second transfer robot are arranged at the same vertical level, and
a transfer direction of the first transfer robot is parallel with a transfer direction of the second transfer robot.

12. The substrate processing apparatus of claim 1, wherein the share module transfers the substrate in a vertical direction, and
the share module delivers the substrate to any one of the first transfer robot and the second transfer robot.

13. A substrate processing apparatus comprising:
a load port for storing a substrate;
a load lock module configured to substitute an atmosphere of the substrate;
an atmosphere transfer robot (ATR) configured to transfer the substrate between the load port and the load lock module;
a plurality of process chambers for processing the substrate;
a plurality of transfer robots configured to transfer the substrate to any one of the plurality of process chambers; and
a share module arranged adjacent to a transfer chamber in which the plurality of transfer robots are disposed,
wherein the load lock module is arranged between the ATR and the transfer robots and substitutes the atmosphere of the substrate with a normal pressure atmosphere or a vacuum atmosphere,
the plurality of transfer robots include an upper transfer robot and a lower transfer robot which is arranged under the upper transfer robot in a vertical direction, and
the plurality of transfer robots transfer the substrate in a vacuum state.

14. The substrate processing apparatus of claim 13, wherein the share module receives from any one of the plurality of transfer robots a substrate processed in the process chambers and cools the substrate.

15. The substrate processing apparatus of claim 14, wherein the share module further includes a first connection and a second connection which move a substrate in the share module,
the first connection is arranged on the substrate, the second connection is arranged under the substrate, and
the share module is configured to ascend or descend by using the first connection and the second connection.

16. The substrate processing apparatus of claim 13, wherein the upper transfer robot and the lower transfer robot transfer the substrate from the share module to the load lock module.

17. A substrate processing method comprising:
providing a substrate to a cassette;
transferring the substrate from the cassette to a load lock module and substituting a normal pressure atmosphere of the substrate with a vacuum atmosphere;
transferring the substrate to a process chamber and performing a semiconductor process;
transferring the substrate to the load lock module after the semiconductor process and substituting the vacuum atmosphere of the substrate with the normal pressure atmosphere; and
taking the substrate out to the cassette.

18. The substrate processing method of claim 17, wherein the transferring of the substrate to the process chamber is performed by a plurality of transfer robots arranged apart from each other.

19. The substrate processing method of claim 18, wherein the plurality of transfer robots include an upper transfer robot and a lower transfer robot arranged under the upper transfer robot in a vertical direction.

20. The substrate processing method of claim 19, wherein the upper transfer robot and the lower transfer robot transfer different substrates from each other.
